(19) United States
(12) Patent Application Publication
(10) Pub. No.: US 2006/0268951 A1
(43) Pub. Date: Nov. 30, 2006

(54) Nitride-based semiconductor laser diode and method of manufacturing the same

(75) Inventor: Kwang-ki Choi, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/372,205

(22) Filed: Mar. 10, 2006

(30) Foreign Application Priority Data
May 27, 2005 (KR) 10-2005-0045217

(51) Int. Cl. H01S 5/00

(52) U.S. Cl. 372/43.01

(57) ABSTRACT

A nitride-based semiconductor laser diode and a method of manufacturing the same are provided. The nitride-based semiconductor laser diode includes a first material layer, an active material layer, and a second material layer that are sequentially formed; a ridge formed on the second material layer; and a current blocking layer formed of AlGaN on at least one top surface of both ends of the ridge and both lateral surfaces of the ridge.

### CROSS-REFERENCE TO RELATED PATENT APPLICATION

This application claims the benefit of Korean Patent Application No. 10-2005-0045217, filed on May 27, 2005, in the Korean Intellectual Property Office, the disclosure of which is incorporated herein in its entirety by reference.

### BACKGROUND OF THE DISCLOSURE

1. Field of the Disclosure

The present disclosure relates to a semiconductor laser diode, and more particularly, to a nitride-based semiconductor laser diode being made through a simple manufacturing process and having a current blocking layer formed of a material having a high heat-dissipating characteristic, and a method of manufacturing the same.

2. Description of the Related Art

Since semiconductor laser diodes have a smaller size and a lower threshold current for laser oscillation than in conventional laser devices, they are widely used for high speed data transmission, recording, and reading in the field of telecommunications and in laser disc players. Particularly, nitride-based semiconductor laser diodes provide wavelengths in a green to ultraviolet region, such that they are widely used for various applications such as high density optical data recording and reproducing, high-resolution laser printers, and projection TVs. As the semiconductor laser diodes are more widely used in a variety of fields, a ridge waveguide type semiconductor laser diode with a low threshold current and high efficiency has been developed.

FIG. 1 is a plan view of a conventional ridge waveguide type semiconductor laser diode, and FIG. 2 is a schematic cross-sectional view of portion A of FIG. 1.

Referring to FIGS. 1 and 2, a first material layer 1, an active layer 2, and a second material layer 3 are sequentially formed, and a ridge 4 is formed at an upper portion of the second material layer 3. Also, a first current blocking layer 5 made of dielectric material is formed on the surface of the second material layer 3 except for a top surface of the ridge 4. The first current blocking layer 5 is formed to control a lateral mode. Second current blocking layers 11 and 13 are formed on both ends of the ridge 4 to prevent current from being supplied to regions around a light emitting surface 10 and a light reflecting surface 12, so that a catastrophic optical damage (COD) level in the ridge waveguide type semiconductor laser diode can be ameliorated. The second current blocking layers 11 and 13 enclose both ends of the ridge 4 to prevent current from being supplied to top surfaces of both ends of the ridge 4. These second current blocking layers 11 and 13 are made of dielectric materials such as SiO₂, Al₂O₃, SiN, and TiN.

In the semiconductor laser diode with the aforementioned structure, however, the second current blocking layers 11 and 13 are formed on both ends of the ridge 4 by forming the first current blocking layer 5 to cover both sides of the ridge 4, depositing a dielectric material on the first current blocking layer 5 and patterning the deposited material using photolithography, thereby complicating the manufacturing process. Also, since the first current blocking layer 5 and the second current blocking layers 11 and 13 are made of dielectric materials with low thermal conductivity, heat is not efficiently dissipated from the semiconductor laser diode around the light emitting surface 10 and the light reflecting surface 12. Therefore, the reliability of the semiconductor laser diode is lowered.

### SUMMARY OF THE DISCLOSURE

The present invention may provide a nitride-based semiconductor laser diode being made through a simple manufacturing process and having an improved structure with a current blocking layer formed of a material having a high heat-dissipating characteristic, and a method of manufacturing the same.

According to an aspect of the present invention, there may be provided a nitride-based semiconductor laser diode including: a first material layer, an active material layer, and a second material layer that are sequentially formed; a ridge formed on the second material layer; and a current blocking layer formed of AlGaN on at least one top surface of both ends of the ridge and both lateral surfaces of the ridge.

The current blocking layer may extend to top surfaces of the second material layer that is located at both sides of the ridge.

The first material layer, the active layer, and the second material layer may be formed of at least one material selected from the group consisting of GaN, InGaN, AlGaN, and AlInGaN.

A bonding metal layer may be deposited on a top surface of the current blocking layer and a top surface of the ridge exposed by the current blocking layer.

According to another aspect of the present invention, there is provided a method of manufacturing a nitride-based semiconductor laser diode, the method including: sequentially growing and stacking a first material layer, an active layer, and a second material layer; forming an etch mask with a predetermined shape on a top surface of the second material layer; forming a ridge by etching a top portion of the second material layer using the etch mask; removing at least one end of both ends of the etch mask to expose at least one top surface of both ends of the ridge; re-growing a current blocking layer formed of AlGaN on the exposed end top surface and both lateral surfaces of the ridge; and removing the etch mask.

After the removing of the etch mask, the method may further include depositing a bonding metal layer on a surface of the current blocking layer and on a top surface of the ridge exposed by the current blocking layer.

The etch mask may be formed by forming a material layer on a top surface of the second material layer and patterning the material layer through photolithography and etching. The material layer may be formed of SiO₂.

The removing of the at least one end of both the ends of the etch mask may be carried out by selective wet etching.

### BRIEF DESCRIPTION OF THE DRAWINGS

The above and other features and advantages of the present invention are described in detailed exemplary embodiments thereof with reference to the attached drawings in which:

FIG. 1 is a plan view of a conventional semiconductor laser diode;

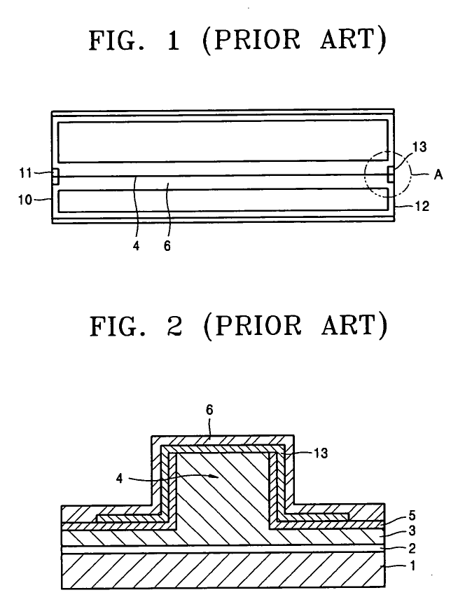

FIG. 2 is a schematic cross-sectional view of portion A of FIG. 1;

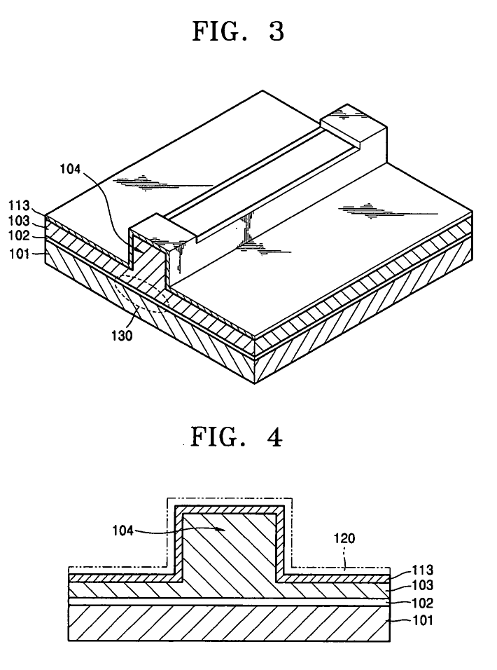

FIG. 3 is a perspective view of a nitride-based semiconductor laser diode according to an embodiment of the present invention;

FIG. 4 is a cross-sectional view taken from a ridge portion located in the vicinity of a light emitting surface in FIG. 3;

FIGS. 5A through 5F are perspective views illustrating a method of manufacturing a nitride-based semiconductor laser diode according to an embodiment of the present invention; and

FIG. 6 is an SEM photograph showing an etch mask and a current blocking layer in the method of manufacturing the nitride-based semiconductor laser diode illustrated in FIGS. 5A through 5F, the etch mask being formed of SiO₂ on a top surface of a ridge, the current blocking layer being formed at both sides of the ridge by re-growing an AlGaN layer.

### DETAILED DESCRIPTION OF EXEMPLARY EMBODIMENTS

The present invention will now be described more fully with reference to the accompanying drawings, in which exemplary embodiments of the invention are shown. Like reference numerals in the drawings denote like elements.

A nitride-based semiconductor laser diode of the present invention is not limited to stacked structures that will be illustrated according to exemplary embodiments of the present invention, and other embodiments including other kinds of nitride-based, group III-V compound semiconductor materials can be produced.

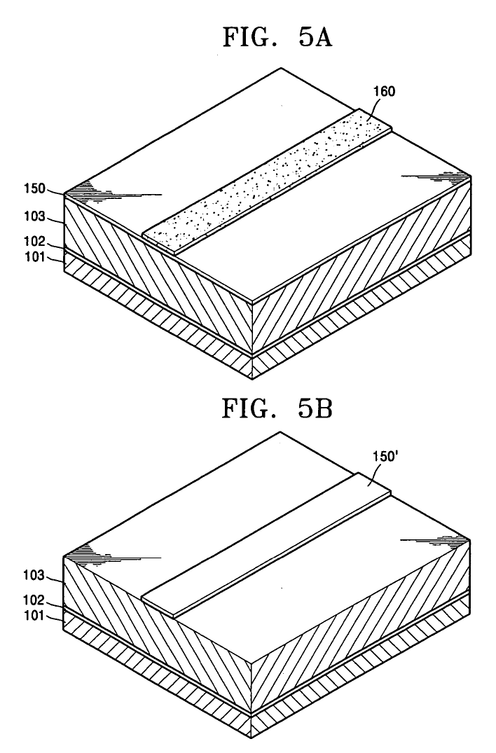

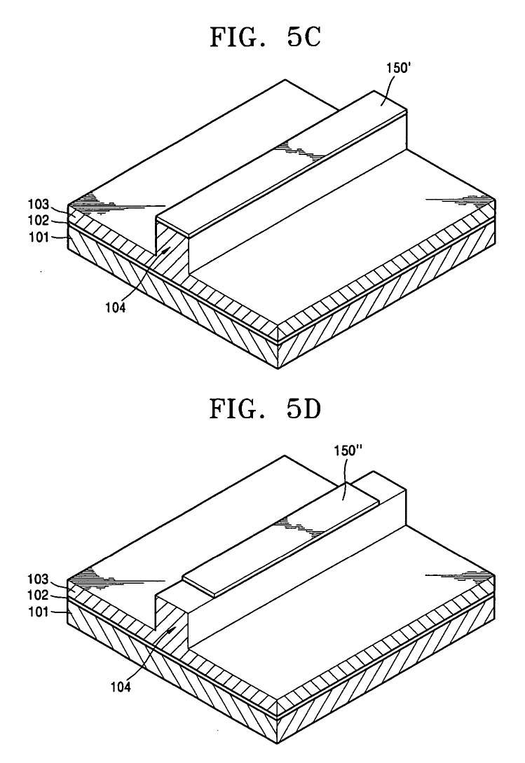

FIG. 3 is a perspective view of a nitride-based semiconductor laser diode according to an embodiment of the present invention, and FIG. 4 is a cross-sectional view taken from a ridge portion located in the vicinity of a light emitting surface in FIG. 3;

Referring to FIGS. 3 and 4, a first material layer 101, an active layer 102, and a second material layer 103 are sequentially formed. At an upper portion of the second material layer 103, a ridge 104 is formed to reduce a threshold current for laser oscillation and to obtain mode stability. The first material layer 101, the active layer 102, and the second material layer 103 may be formed of GaN-based, group III-V nitride compound semiconductors, and specifically, at least one material selected from the group consisting of GaN, InGaN, AlGaN, and AlInGaN. For example, the first and second material layers 101 and 103 may be an n-GaN layer and a p-GaN layer, respectively. Also, the active layer 102 may be a material layer for emitting light by carrier recombination of an electron and a hole, such as an AlInGaN layer or InGaN layer with a single or multi-quantum well structure.

A current blocking layer 113 is formed on both lateral surfaces of the ridge 104 and on top surfaces of both ends of the ridge 104 where a light emitting surface 130 and a light reflecting surface (not shown) are respectively located. The current blocking layer 113 further extends to top surfaces of the second material layer 103, which are located at both sides of the ridge 104. The current blocking layer 113 is formed on both lateral surfaces of the ridge 104 and on the top surfaces of the second material layer 103 to control a lateral mode. The current blocking layer 113 also encloses both ends of the ridge 104 to prevent current from being supplied to the top surfaces of both ends of the ridge 104 which are located in the vicinity of the light emitting surface 130 and the light reflecting surface, so that catastrophic optical damage (COD) level can be ameliorated.

The current blocking layer 113 may be formed of AlGaN having very high thermal conductivity. For example, if the second material layer 103 is a P-type material layer, the current blocking layer 113 may be an n-AlGaN layer or undoped AlGaN layer. Although SiO₂, Al₂O₃, and SiN with thermal conductivity of 1.2 W/mk, 36 W/mk, and 16 W/mk, respectively, are used for a current blocking layer according to the related art, AlGaN with high thermal conductivity of 130 W/mk or more may be used for the current blocking layer 113 according to the present invention. In this way, since the current blocking layer 113 which encloses both ends of the ridge 104 is made of AlGaN having high thermal conductivity, heat generated from the light emitting surface 130 and the light reflecting surface can be efficiently dissipated to the outside. Though the current blocking layer 113 encloses both ends of the ridge 104 where the light emitting surface 130 and the light reflecting surface are respectively located, the current blocking layer 113 can enclose only a portion of the ridge 104 where the light emitting surface 130 is located.

A bonding metal layer 120 may be deposited on a top surface of the current blocking layer 113 and a top surface of the ridge 104 exposed through the current blocking layer 113. The bonding metal layer 120 contacts the top surface of the ridge 104 to apply current to the top surface of the ridge 104. That is, the bonding metal layer 120 functions as an electrode.

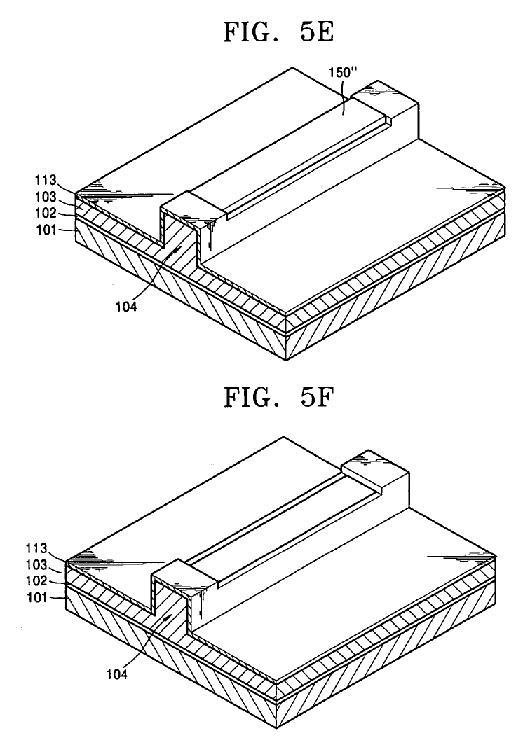

A method of manufacturing a nitride-based semiconductor laser diode will now be described. FIGS. 5A through 5F are perspective views illustrating a method of manufacturing a nitride-based semiconductor laser diode according to an embodiment of the present invention.

Referring to FIG. 5A, a first material layer 101, an active layer 102, and a second material layer 103 are sequentially grown and stacked. Here, the first material layer 101 and the second material layer 103 may have multiple layer structures. As mentioned above, the first material layer 101, the active layer 102, and the second material layer 103 may be formed of at least one material selected from the group consisting of GaN, InGaN, AlGaN, and AlInGaN. For example, the first and second material layers 101 and 103 may be an n-GaN layer and a p-GaN layer, respectively, and the active layer 102 may be an AlInGaN or InGaN layer. Next, a material layer 150 may be formed on a top surface of the second material layer 103. The material layer 150 may be formed of SiO₂. A photoresist 160 is deposited on the entire top surface of the material layer 150 formed of SiO₂, and the deposited photoresist 160 is patterned through photolithography.

Referring to FIG. 5B, the material layer 150 is etched using the photoresist 160 patterned in FIG. 5A to form a SiO₂ etch mask 150′ in a predetermined pattern, for example, a strip pattern, on the top surface of the second material layer 103. Next, the photoresist 160 is removed.

Referring to FIG. 5C, the second material layer 103 is etched to a predetermined depth using the etch mask 150′ to form a ridge 104 at an upper portion of the second material layer 103 having a predetermined height.

Referring to FIG. 5D, both ends of the etch mask 150′ formed on both ends of the ridge 104 are removed by etching. In this case, both ends of the etch mask 150′ may be removed through selective wet etching of the SiO₂ layer and the second material layer 103. Although both ends of the etch mask 150′ where a light emitting surface and a light reflecting surface are respectively located are removed, only one end of the etch mask 150′ where the light emitting surface is located can be removed.

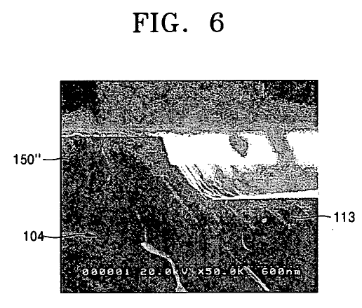

Referring to FIG. 5E, an AlGaN layer with high thermal conductivity is re-grown on the surface of the second material layer 103 exposed by the etch mask 150″ whose both ends are removed, thereby forming a current blocking layer 103. Specifically, the current blocking layer 113 is formed on top surfaces of both ends of the ridge 104, both lateral surfaces of the ridge 104, and top surfaces of the second material layer 103 that are located at both sides of the ridge 104. The current blocking layer 113 may be an n-AlGaN layer or undoped AlGaN layer, for example, if the second material layer 103 is a P-type material layer. If only one end of the etch mask 150′ where the light emitting surface is located is removed, the current blocking layer 113 encloses one end of the ridge 104 where the light emitting surface is located. FIG. 6 is an SEM photograph showing the etch mask 150″ formed of SiO₂ on the top surface of the ridge 104 and the current blocking layer 113 formed at both sides of the ridge 104 by re-growing an AlGaN layer.

Referring to FIG. 5F, the etch mask 150″ that remains on the top surface of the ridge 104 is removed, and then a bonding metal layer (not shown) is deposited on a surface of the current blocking layer 113 and a top surface of the ridge 104 exposed by the current blocking layer 113. In this way, a nitride-based semiconductor laser diode is manufactured.

As described above, according to the present invention, the current blocking layer, an AlGaN layer with high thermal conductivity, is formed on both ends of the ridge, so that heat dissipation from the light emitting surface and the light reflecting surface can be increased and thereby the COD level can be improved. Further, carrier densities of the light emitting surface and the light reflecting surface can be reduced. In addition, the current blocking layer is formed on both ends and both lateral surfaces of the ridge by re-growing the AlGaN layer, thereby simplifying the manufacturing process.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nitride-based semiconductor laser diode comprising:
a first material layer, an active material layer, and a second material layer that are sequentially formed;
a ridge formed on the second material layer; and
a current blocking layer formed of AlGaN on at least one top surface of both ends of the ridge and both lateral surfaces of the ridge.

2. The nitride-based semiconductor laser diode of claim 1, wherein the current blocking layer extends to top surfaces of the second material layer that are located at both sides of the ridge.

3. The nitride-based semiconductor laser diode of claim 1, wherein the first material layer, the active layer, and the second material layer are formed of at least one material selected from the group consisting of GaN, InGaN, AlGaN, and AlInGaN.

4. The nitride-based semiconductor laser diode of claim 1, wherein a bonding metal layer is deposited on a top surface of the current blocking layer and a top surface of the ridge exposed by the current blocking layer.

5. A method of manufacturing a nitride-based semiconductor laser diode, the method comprising:
sequentially growing and stacking a first material layer, an active layer, and a second material layer;
forming an etch mask with a predetermined shape on a top surface of the second material layer;
forming a ridge by etching a top portion of the second material layer using the etch mask;
removing at least one end of both ends of the etch mask to expose at least one top surface of both ends of the ridge;
re-growing a current blocking layer formed of AlGaN on the exposed end top surface and both lateral surfaces of the ridge; and
removing the etch mask.

6. The method of claim 5, wherein the current blocking layer is also re-grown on top surfaces of the second material layer that are located at both sides of the ridge.

7. The method of claim 5, further comprising, after the removing of the etch mask, depositing a bonding metal layer on a surface of the current blocking layer and on a top surface of the ridge exposed by the current blocking layer.

8. The method of claim 5, wherein the first material layer, the active layer, and the second material layer are formed of at least one material selected from the group consisting of GaN, InGaN, AlGaN, and AllnGaN.

9. The method of claim 5, wherein the etch mask is formed by forming a predetermined material layer on a top surface of the second material layer and patterning the material layer through photolithography and etching.

10. The method of claim 9, wherein the material layer is formed of SiO₂.

11. The method of claim 5, wherein the removing of the at least one end of both the ends of the etch mask is carried out by selective wet etching.
